(19) United States
(12) Patent Application Publication
(10) Pub. No.: US 2018/0033949 A1
(43) Pub. Date: Feb. 1, 2018

(54) INTEGRATED CIRCUIT FOR SELF-POWERED PIEZOELECTRIC-BASED ACCELERATION PULSE EVENT DETECTION WITH FALSE TRIGGER PROTECTION LOGIC AND APPLICATIONS

(71) Applicants: Jahangir S. Rastegar, Ronkonkoma, NY (US); Ziyuan Feng, Ronkonkoma, NY (US)

(72) Inventors: Jahangir S. Rastegar, Ronkonkoma, NY (US); Ziyuan Feng, Ronkonkoma, NY (US)

(73) Assignee: Omnitek Partners LLC, Ronkonkoma, NY (US)

(21) Appl. No.: 15/659,553

(22) Filed: Jul. 25, 2017

Related U.S. Application Data
(60) Provisional application No. 62/510,179, filed on May 23, 2017.
(60) Provisional application No. 62/367,075, filed on Jul. 26, 2016.

(51) Int. Cl. H01L 41/113; H02N 2/18

(52) U.S. Cl. CPC H01L 41/113; H02N 2/181

(57) ABSTRACT

An inertial switch including piezoelectric and external event detection circuitry

### CROSS-REFERENCE TO RELATED APPLICATION

This application claims the benefit of U.S. Provisional Application Nos. 62/367,075 filed on Jul. 26, 2016 and 62/510,179, filed on May 23, 2017, the entire contents of each of which is incorporated herein by reference.

### BACKGROUND

### 1. Field

The present disclosure relates generally to an integrated circuit (IC) for use with piezoelectric elements to construct self-powered acceleration pulse event detection devices with false trigger protection logic, and more particularly for detecting acceleration pulses with longer than a prescribed duration and higher than a prescribed level, such as those generated during impact.

### 2. Prior Art

A G-switch or inertial switch is a switch that can change its state, for example, from open to close, in response to acceleration and/or deceleration. Hereinafter, the term acceleration is intended to also include deceleration and the disclosed devices are readily seen by those skilled in the art that can be configured to react to either acceleration or deceleration events by their reorientation. For example, when the acceleration along a particular direction exceeds a certain threshold value, the inertial switch changes its state, which change can then be used to trigger an electrical circuit controlled by the inertial switch. Inertial switches are employed in a wide variety of applications such as automobile airbag deployment systems, vibration alarm systems, detonators for artillery projectiles, and motion-activated light-flashing footwear. Description of several representative prior-art inertial switches can be found, for example, in U.S. Pat. Nos. 7,212,193, 6,354,712, 6,314,887, 5,955,712, 5,786,553, 4,178,492, and 4,012,613, the teachings of all of which are incorporated herein by reference.

To ensure safety and reliability, inertial switches for electrical circuits should not activate (open or close electrical circuits) during acceleration events which may occur during manufacture, assembly, handling, transport, accidental drops, or other similar accidental events. Additionally, once under the influence of an acceleration profile particular to the firing of ordinance from a gun or other similarly intended events such as impact (deceleration) events of long enough duration such as vehicular accidents as to be distinguished from encountering a bump or pot hole in the road or vibration encountered in rough roads such as for off-road vehicles, or the like, the device should activate with high reliability. In many applications, these two requirements often compete with respect to acceleration magnitude, but differ greatly in impulse. For example, an accidental drop may well cause very high acceleration levels—even in some cases higher than the firing of a shell from a gun. However, the duration of this accidental acceleration will be short, thereby subjecting the inertial igniter to significantly lower resulting impulse levels. It is also conceivable that the inertial switch will experience incidental low but long-duration accelerations, whether accidental or as part of normal handling, which must be guarded against activation. Again, the impulse given to the miniature inertial switch will have a great disparity with that given by the intended activation acceleration profile because the magnitude of the incidental long-duration acceleration will be quite low.

The disclosed integrated circuit (IC) enables the user to readily construct self-powered piezoelectric-based acceleration pulse event detection, i.e., to readily construct self-powered “inertial switches” with false trigger protection logic for almost any application circuitry, including a number of applications described in detail. The self-powered “inertial switches” constructed disclosed herein may provide one or more of the following advantages over prior art mechanical or MEMS-based “G switches” or “inertial switches”:
By only using a very few external electronic components, for example one resistor and one capacitor, the inertial switches can be programmed to switch at any desired minimum acceleration or deceleration level and its duration;
Provide inertial switches that are self-powered and passive, and that even be used to switch-on other electronic circuit power when an event is detected, for example initiate transmission of emergency signals, to save power and prolong the life of the using system;
Provide inertial switches for electronic circuits that can be mounted directly onto the electronics circuits boards or the like, thereby significantly simplifying the electrical and electronic circuitry, simplifying the assembly process and total cost; significantly reducing the occupied volume, and eliminating the need for physical wiring to and from the inertial switches;
Provide inertial switches that eliminate the need for accelerometers and processors with their own power sources to measure the imparted acceleration or deceleration pulses and measure their duration to determine if a prescribed acceleration pulse event is to be considered as detected;
The disclosed small integrated circuit (IC) allows the construction of inertial switches that are very small and occupy a very small volume, which is a highly desirable feature for many electronic devices such as handheld devices, particularly for use in munitions without occupying large volumes;
Provide inertial switches for electrical circuits that can be hermetically sealed to simplify storage and increase their shelf life.

### SUMMARY

A need therefore exists for an integrated circuit (IC) that can be used to construct piezoelectric-based self-powered acceleration pulse event detection devices with false trigger protection logic, i.e., hereinafter referred to as “inertial impulse switches” and in short “inertial switches”. The self-powered “inertial switches” should be capable of detecting acceleration pulses that are longer in duration and higher in amplitude than prescribed levels, such as those experienced during munitions firing or target impact, or impacts during a vehicles accident, or the drop of a package that could damage its content, or the like. The IC should require very few discrete electronic components to “program” the inertial switch to detect a prescribed acceleration pulse and to be configured to perform the indicated pyrotechnic initiation, energy harvesting, and other similar functions.

Accordingly, an integrated circuit (IC) is disclosed for use with piezoelectric elements to construct self-powered acceleration pulse event detection devices with false trigger protection logic. The self-powered “inertial switches” constructed with this IC can detect acceleration pulses that are longer in duration and higher in amplitude than prescribed levels, such as those experienced during munitions firing or target impact, or impacts during a vehicles accident, or the drop of a package that could damage its content, or the like.

Also disclosed are method of using the said integrated circuit (IC) for constructing piezoelectric-based self-powered “inertial switches”; and self-powered pyrotechnic initiation devices; and energy harvesting devices that efficiently collects the electrical energy generated by the piezoelectric. The constructed devices perform the indicated functions upon detection of prescribed acceleration pulse and are provided with false trigger protection.

It is appreciated by those skilled in the art that in most applications, particularly in munitions applications, it is critical that the aforementioned piezoelectric-based self-powered “inertial switches”, pyrotechnic initiation devices, and energy harvesting devices used to power munitions electronics and the like, to be reliable and be provided with false trigger protection capability. To ensure reliability and false trigger protection capability, these and the like devices must be capable of differentiating the prescribed acceleration pulse events as described by minimum acceleration pulse magnitude and duration (the so-called all-fire events for the case of gun-fired munitions and mortars) from acceleration events which may occur during manufacture, assembly, handling, transport, accidental drops, etc. Similar considerations are critical in many non-munitions applications, for example, for differentiating a vehicle impact due to an accident from hitting of a pot hole or the like, for deploying air bags. In many applications, these two requirements compete with respect to acceleration magnitude, but differ greatly in their duration. For example:
In munitions, an accidental drop may well cause very high acceleration levels—even in some cases higher than the firing of a shell from a gun. However, the duration of this accidental acceleration will be short, thereby subjecting the inertial switch or other aforementioned devices to significantly lower resulting impulse levels.
It is also conceivable that the inertial switch or other aforementioned devices will experience incidental long-duration acceleration and deceleration cycles, whether accidental or as part of normal handling or vibration during transportation, during which it must be guarded against false triggering. Again, the impulse input to the device will have a great disparity with that given by the intended acceleration profile because the magnitude of the incidental long-duration acceleration will be quite low.

### BRIEF DESCRIPTION OF THE DRAWINGS

These and other features, aspects, and advantages of the apparatus of the present invention will become better understood with regard to the following description, appended claims, and accompanying drawings where:

FIG. 1 illustrates a typical piezoelectric-based electrical energy generator component of a self-powered device that is intended to generate electrical energy when subjected to an acceleration pulse.

FIG. 2 illustrates a model of a piezoelectric element of the generator of FIG. 1.

FIG. 3 illustrates plots of typical generated piezoelectric charges as a function time during a typical short duration acceleration pulse loading.

FIG. 4 illustrates the schematic of the integrated circuit (IC) of the present invention as configured with a piezoelectric electrical energy generator and electronic components to provide an inertial switch for detecting a prescribed acceleration pulse with false trigger protection capability.

FIG. 5 illustrates the schematic of FIG. 4 with the primary functions of the components of the self-powered acceleration pulse event detection device with false trigger protection logic and resetting capability indicated by blocks drawn with dotted lines.

FIG. 6 illustrates the inertial switch embodiment of FIG. 5, as to be fabricated using the integrated circuit (IC) embodiment of the present invention by the addition of external components.

FIG. 7 illustrates the schematic of the integrated circuit (IC) of the present invention as configured with a piezoelectric electrical energy generator and other external components to construct a self-powered heating filament based pyrotechnic initiator all-fire detection and no-fire (false trigger) protection capability.

FIG. 8 illustrates the schematic of the integrated circuit (IC) of the present invention as configured with a piezoelectric electrical energy generator and other external components to construct an efficient energy harvesting device that harvests electrical energy and stores it in the storage capacitor only after detecting a prescribed acceleration pulse such as the all-fire event in munitions.

FIG. 9 illustrates the schematic of the integrated circuit (IC) of the present invention as configured with a piezoelectric electrical energy generator and electronic components to provide an inertial switch for detecting a prescribed acceleration pulse based on a prescribed acceleration magnitude and duration of the pulse at or above the prescribed magnitude with false trigger protection capability.

### DETAILED DESCRIPTION OF THE PREFERRED EMBODIMENT

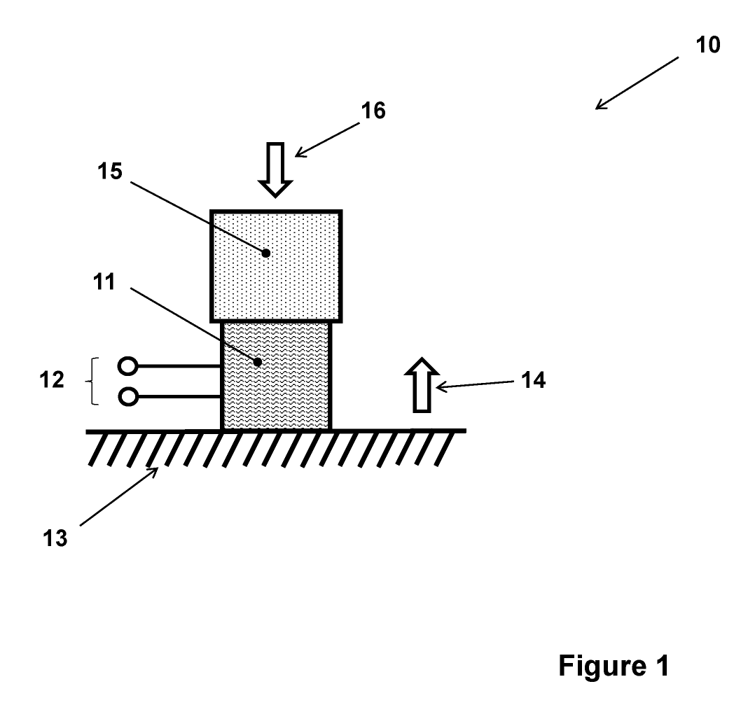

A typical piezoelectric electrical energy generator 10, usually with a stack type piezoelectric element 11, that is used in self-powered devices to generate electrical energy when the device is subjected to shock loading, for example due to an acceleration pulse, is shown in the schematic of FIG. 1. In the configuration shown in FIG. 1, the piezoelectric electrical energy (charge) generator 10 is shown as rigidly attached to a base structure 13, which is considered to be subjected at certain point in time to an acceleration pulse in the direction of the arrow 14. A relatively rigid mass 15 may also be required to react to the acceleration 14 and apply a resulting compressive force to the piezoelectric element 11. Then as a result of the said compressive force and the internal normal compressive pressure generated in the piezoelectric element 11 due to its own mass as a result of the said acceleration pulse, the piezoelectric element 11 is strained (deformed) axially, and thereby would generate electrical charges at its electrodes as is well known in the art. The leads 12, properly connected to the electrodes of the piezoelectric element, would make the generated charges available for collection and conditioning.

In a typical piezoelectric-based self-powered device application such as the present “inertial switches” constructed with the disclosed integrated circuit (IC), a piezoelectric electrical energy generator similar to the one shown in FIG. 1 is used to provide electrical energy (charges) to that is used to power the device to perform its described function. In the present case, the said piezoelectric electrical energy generator is considered to generate electrical energy as a result of a shock loading event due to the aforementioned acceleration pulse. The piezoelectric electrical energy generator 10 is thereby functioning as a so-called energy harvester to convert mechanical energy to electrical energy to power the self-powered device as well as an acceleration pulse sensor to be described.

It is appreciated by those skilled in the art that shock loading pulse applied to the piezoelectric element 11 of the piezoelectric electrical energy generator 10 may also be due to direct application of a compressive force shown by the arrow 16 in FIG. 1. The applied compressive force may be the result of impact with an object, a pressure wave, or the like.

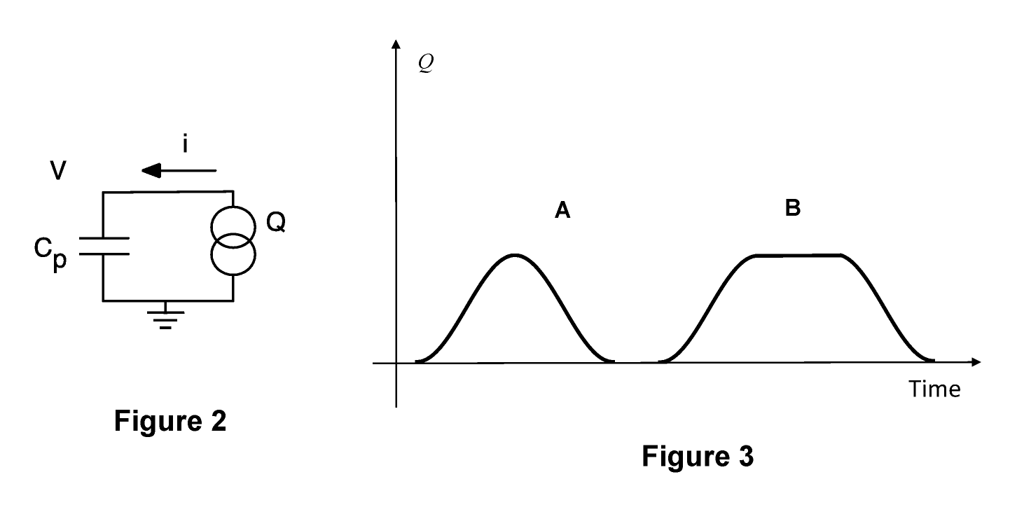

A stand-alone piezoelectric (usually in stack form) element can be modeled as a capacitor Cₚ connected in parallel to a charge source Q as shown in FIG. 2. The charge source Q generates charge proportional to the axial (normal) strain of the piezoelectric element as it is subjected to axial (normal) loading, and thereby sends the charge as current i to the capacitor Cₚ of the piezoelectric element. The charges accumulated on the capacitor Cₚ produces a voltage V, which is the aforementioned so-called open-circuit voltage of the piezoelectric element. When the piezoelectric element is connected to another circuitry, the generated charge and current are the same, but due to the resulting charge exchange with the other circuitry, the in circuit voltage of the piezoelectric element may be different from the open circuit voltage V.

Two typical plot A and B of the profile of the open-circuit charge level on the piezoelectric element (FIG. 2) as it is subjected to a short duration acceleration pulse such as munitions firing or impact loading as a function of time are shown in FIG. 3. The maximum amount of charges Q (in Coulomb) is dependent on the size of the piezoelectric element and the applied impact force levels. In most cases of interest, the acceleration pulse may be from tens of microseconds to several milliseconds in duration.

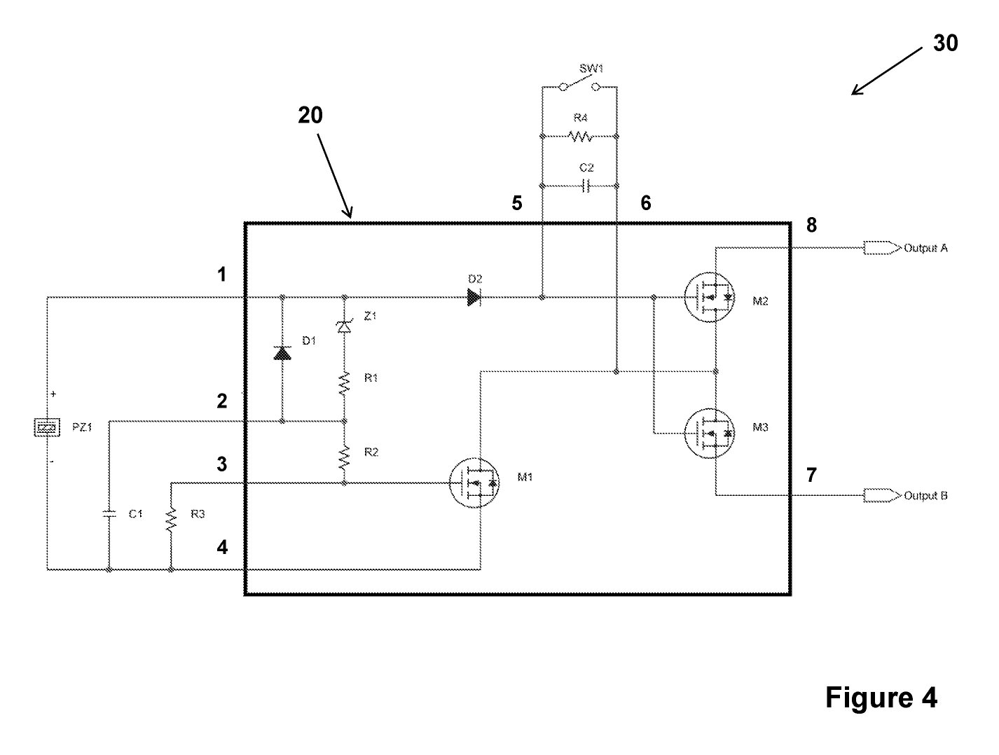

The schematic of the integrated circuit (IC) embodiment 20 of the present invention is shown in FIG. 4, as indicated by the solid rectangular box. The integrated circuit 20 may be fabricated using MOS technology or the like. Here, the basic design and function performed by the integrated circuit (IC) embodiment 20 are described in the context its use in the construction of self-powered acceleration pulse event detection devices with false trigger protection logic and resetting capability, indicated by the numeral 30. As was previously indicated, the present self-powered “inertial switches” constructed with the integrated circuit (IC) embodiment 20 can detect acceleration pulses that are longer in duration and higher in amplitude than certain prescribed levels, such as those experienced during munitions firing or target impact, or impacts during a vehicles accident, or the drop of a package that could damage its content, or the like. In the schematic of FIG. 4, the setting (programming) of a prescribed acceleration pulse magnitude and duration thresholds are shown to be accomplished by the choice of the resistance of the resistor R3 and the capacitance of the capacitor C1, both external to the integrated circuit (IC) embodiment 20 as is described later in this disclosure.

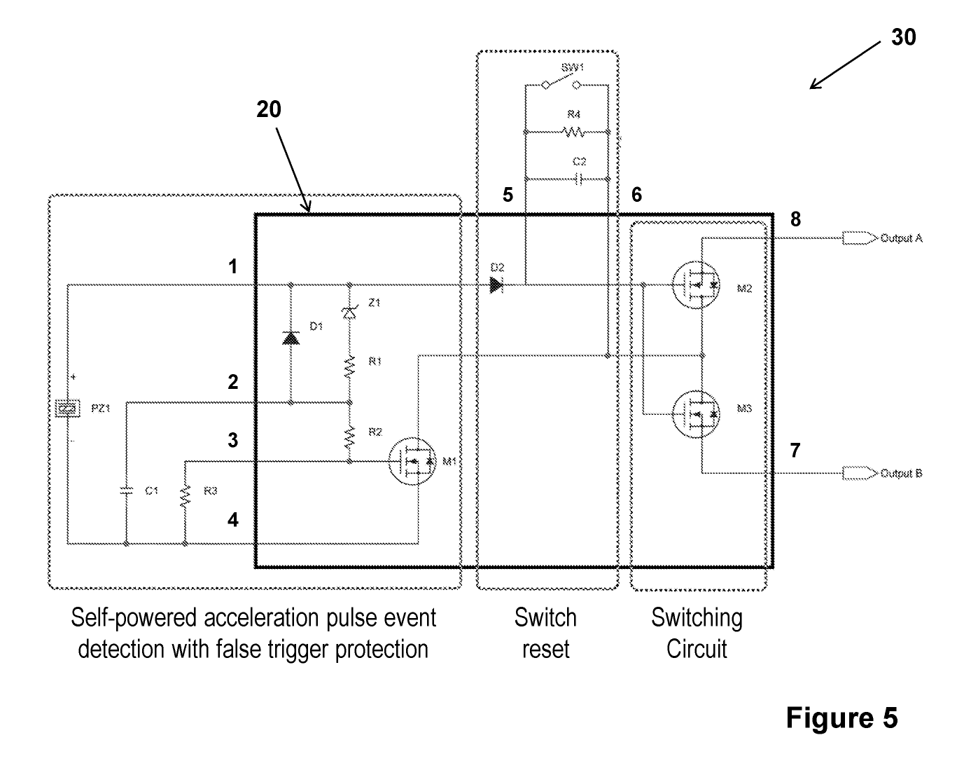

The integrated circuit IC 20 based “self-powered acceleration pulse event detection device with false trigger protection logic and resetting capability” 30 of FIG. 4, hereinafter referred to shortly as “inertial switch 30”, is redrawn in FIG. 5 to describe the functionality of its various components.

The primary functions performed by the components of the inertial switch 30 of FIG. 4 may presented by the three function blocks shown with dotted lines in FIG. 5. As can be seen in FIG. 5, the three function blocks are the “Self-powered acceleration pulse event detection with false trigger protection” block; the “Switch reset”; and the “Switching circuit”.

When the piezoelectric element PZ1 of the inertial switch 30, which may be as shown in FIG. 1, is subjected to an acceleration pulse, such as an acceleration in the direction of the arrow 14 in FIG. 1, the piezoelectric element will generate an open-circuit charge profile such as the one shown in FIG. 3.

As was previously described, the present inertial switch 30 are designed to be capable of differentiating a prescribed acceleration pulse events as described by a minimum acceleration pulse magnitude and a minimum of its duration (the so-called all-fire events for the case of gun-fired munitions and mortars) from other acceleration events that may occur during manufacture, assembly, handling, transport, accidental drops, etc. The said event is hereinafter referred to as the “prescribed acceleration pulse event”. To detect the occurrence of a prescribed acceleration pulse event, the profile of the charge voltage generated by the piezoelectric element PZ1 of the inertial switch 30 must satisfy the event minimum magnitude and its minimum duration (at the minimum magnitude) conditions. In the inertial switch 30 of FIG. 5, the said magnitude and duration thresholds are configured by the resistance of the resistor R3 and the capacitance of the capacitor C1, both of which are external components to the integrated circuit embodiment 20.

The aforementioned magnitude threshold of the open-circuit piezoelectric charge voltage, which is proportional to the magnitude of the acceleration pulse experienced by the piezoelectric element and its duration is determined from the voltage of the capacitor C1. It is appreciated by those skilled in the art that under relatively low acceleration levels, such as those experienced during transportation induced vibration, the voltage across the piezoelectric element PZ1 is lower than the Z1 Zener diode voltage and since the diode D1 also blocks the current flow into the capacitor C1, the capacitor C1 stays discharged. In the integrated circuit 20, the Zener diode Z1 is generally used to set a minimum voltage threshold level for blocking charging of the capacitor C1 by charges generated by the piezoelectric element in response to the aforementioned low acceleration levels such as those due to transportation induced accelerations. At such low acceleration levels, no current will pass through the resistor R1 to charge the capacitor C1, and the MOSFET M1 is in cut-off mode and no current passes to the output ports. In general, the capacitance of the capacitor C1 is selected to be very low and the resistance of the resistor R1 is selected to be high so that a very small portion of the electrical energy generated by the piezoelectric element PZ1 is consumed by the Z1, R1 and C1 circuit.

In the inertial switch 30 of FIG. 5, the resistors R1 and R2 of the integrated circuit 20 are fixed and by selecting appropriate values for the resistance of the resistor R3 and the capacitance of the capacitor C1, the user sets the aforementioned acceleration pulse magnitude and duration thresholds for the inertial switch 30. In the integrated circuit 20, the MOSFET M1 functions as a signal switch, which is activated when its gate voltage level has been reached.

When the inertial switch 30 of FIG. 5 experiences an acceleration pulse, if the voltage of the charges generated by the piezoelectric element PZ1 passes the Z1 Zener diode voltage, the reverse biased Z1 diode passes current to the capacitor C1, and the capacitor begins to be charged. If the acceleration pulse amplitude passes the prescribed threshold level and lasts longer than the prescribed duration threshold, the gate voltage of the MOSFET M1 will be reached and it is activated. However, if the amplitude of the acceleration pulse is higher than the prescribed threshold level but its duration is below that of the prescribed duration threshold, then the gate voltage of the MOSFET M1 will not be reached, and it is not activated.

Once a prescribed acceleration pulse event has been detected by the detection of aforementioned minimum magnitude and its minimum duration (at the minimum magnitude), the MOSFET M1 is activated as is described above. Upon activation of the MOSFET M1, the capacitor C2 is charged up to a voltage level which is higher than the gate threshold voltage of the MOSFETs M2 and M3, and would allow current to flow in both directions. As a result, the normally open circuit between the integrated circuit (IC) 20 pins 7 and 8 is closed. The inertial switch 30 of FIG. 5 is thereby functions as a normally open inertial switch, which closes the said circuit (between the pins 7 and 8) upon detection of the prescribed acceleration pulse event.

As can be seen in FIG. 5, the components of the “switch reset” function block, i.e., the normally open switch SW1, the capacitor C2 and the resistor R4 are external to the integrated circuit (IC) 20. In the present inertial switch 30, the user has the option of providing the resistor R4 and/or the normally open switch SW1. Without the resistor R4, the charges stored in the capacitor C2 will slowly drain due to unavoidable leakages in the various components of the inertial switch circuitry and once the voltage of the capacitor C2 drops below the gate threshold voltage of the MOSFETs M2 and M3, the close circuit between the pins 7 and 8 is opened. This option of the inertial switch 30 is in effect a normally open inertial switch with latching capability. However, unlike mechanical switches or externally powered switches, the latching state is not permanent. However, for many applications such as in munitions and in other similar cases in which as a result of detection of the prescribed acceleration pulse a system is supposed to react and perform certain action, the present normally open inertial switch is in effect a latching switch.

The user may also choose to provide the resistor R4, FIG. 5. The function of the resistor R4 is to slowly drain the charges in the capacitor C2. By choosing lower resistance for the resistor R2, the rate at which the capacitor C2 charges are drained is increased, therefore the inertial switch remains closed, i.e., the circuit between the pins 7 and 8 remains closed for a shorter period of time.

In some applications, such as during engineering development of devices and systems that are expected to be subjected to acceleration pulses, the user may want to be able to reset the inertial switch state, i.e., to drain the charges in the capacitor C2 to open the circuit between the pins 7 and 8. In such application, a manual or certain control system activated normally open switch SW1, FIG. 5, may be provided to serve as a reset switch. The use would then close the switch SW1 when desired, to drain charges in the capacitor C2 to open the circuit between the pins 7 and 8.

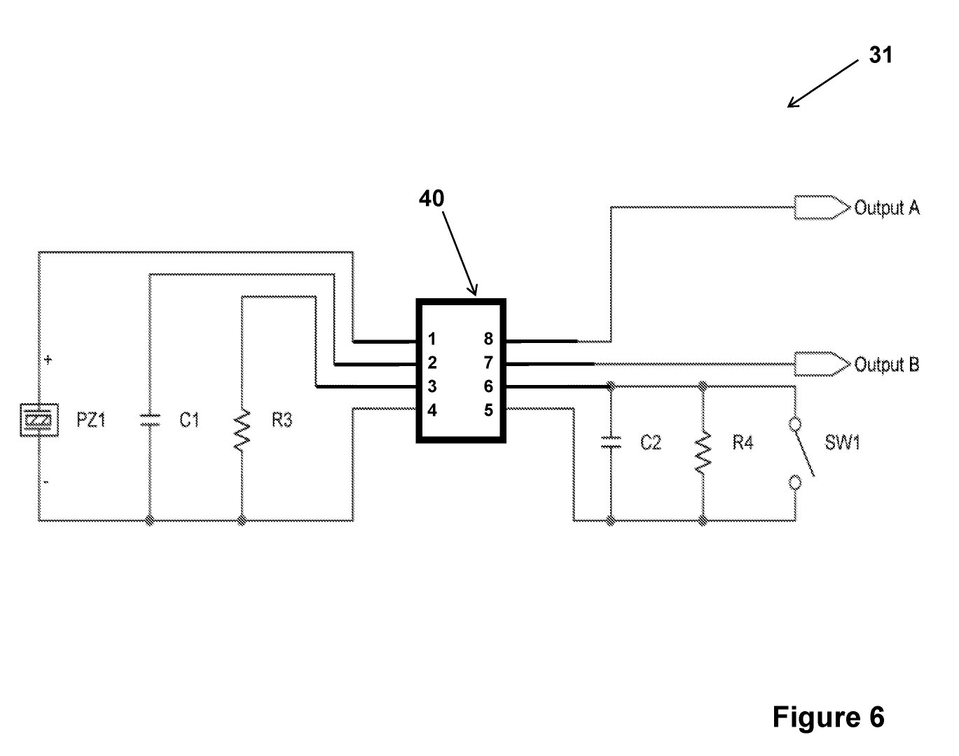

FIG. 6 shows the inertial switch 30 of FIG. 5, as it would be fabricated using the integrated circuit 20 by the addition of the aforementioned external components. The integrated circuit 20 (indicated by the numeral 40 in FIG. 6) is shown with the 8 pins, as numbered in the schematics of FIGS. 4 and 5, for connecting the external components of the inertial switch (indicated by the numeral 31 in FIG. 6).

It is appreciated that 8 pins are the minimum number of pins that are required on the integrated circuit (IC) 40 of FIG. 6 (20 of FIGS. 4 and 5) for the present inertial switch construction. The integrated circuit may, however, be fabricated with additional pins for connecting other components to modify the values of, for examples, resistances of the IC resistors, or change the gate voltage of the MOSFETS, or directly add other external components to provide certain other functionality for the intended application.

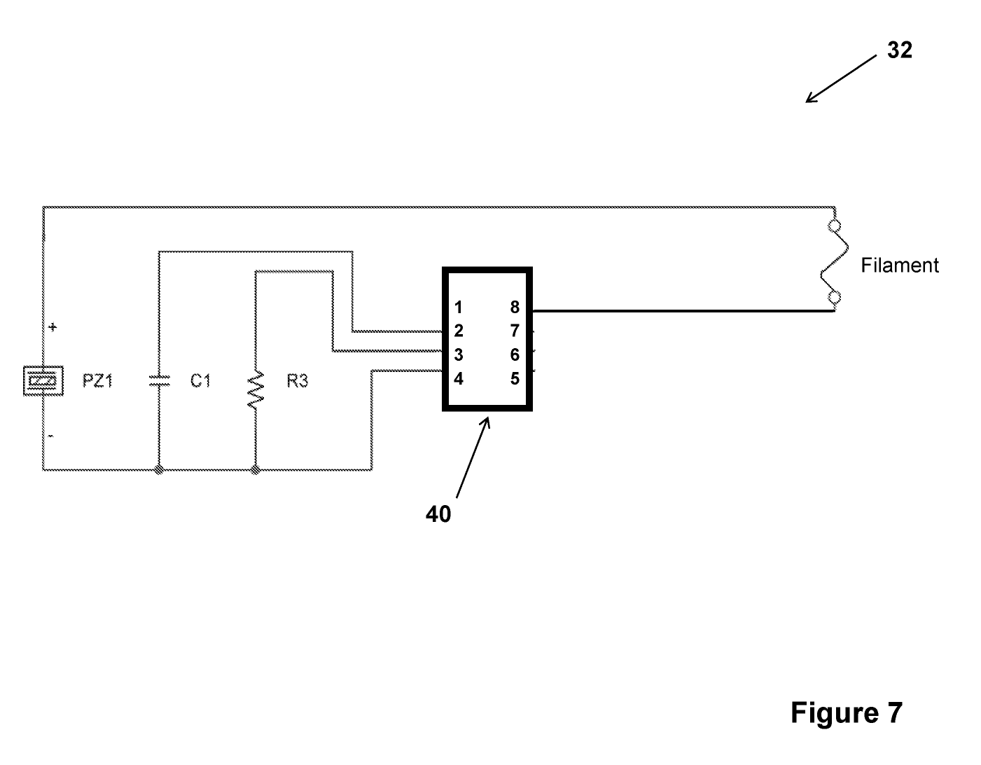

In another embodiment of the present invention shown in FIG. 7, the integrated circuit (IC) 40 of FIG. 6 (20 in FIGS. 4 and 5) is used to construct a self-powered pyrotechnic initiation device 32 with the aforementioned acceleration pulse magnitude and duration detection capability (the so-called all-fire detection capability in munitions) and with false trigger protection capability (the so-called no-fire protection/safety capability in munitions). The self-powered pyrotechnic (electrical) initiation device 32 ignites pyrotechnic material by the heating of the provided low resistance filament. In the self-powered electrical pyrotechnic initiation device, once the prescribed acceleration pulse event (corresponding to all-fire condition in the case of gin-fired munitions) is detected as was previously described by the “Self-powered acceleration pulse event detection with false trigger protection” block shown in the schematic of FIG. 5, the remaining charges generated by the piezoelectric element PZ1 are passed directly through the heating filament. As a result of the current flow, the initiator filament (usually around 1-3 Ohm) is heated to a temperature sufficient to ignite the intended pyrotechnic material. In this embodiment the IC pins (5) and (6) are usually free since a resetting function is not required for such one-shot devices.

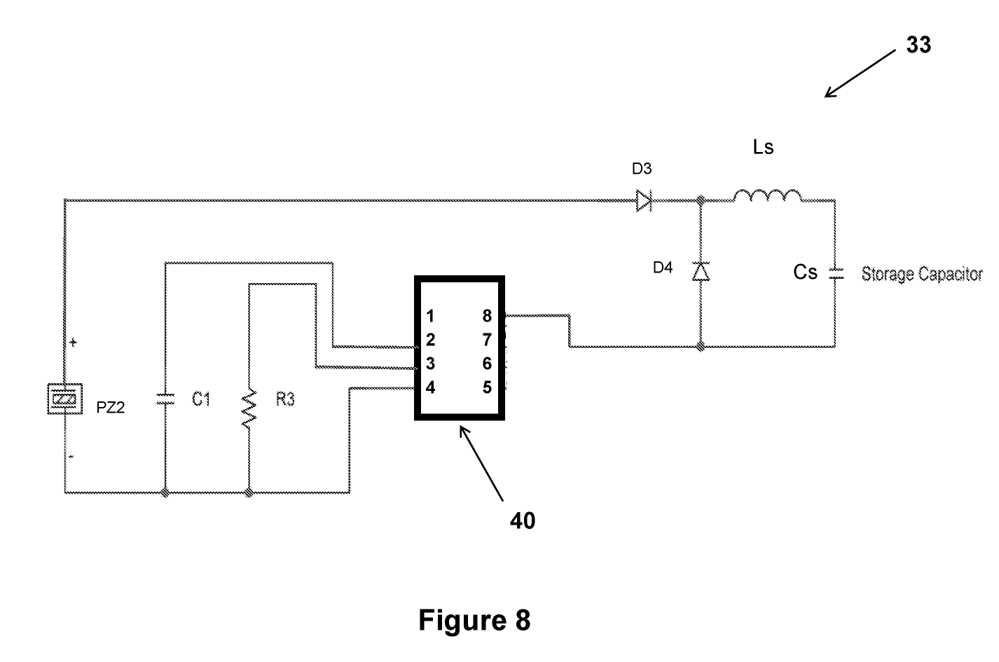

In another embodiment 33 shown in FIG. 8, the integrated circuit (IC) 40 of FIG. 6 (20 in FIGS. 4 and 5) is configured to efficiently collect and store in a storage capacitor the generated electrical energy by the piezoelectric element PZ2 once an aforementioned prescribed acceleration pulse is detected as was described for the embodiments of FIGS. 5, 6 and 7 from the acceleration pulse magnitude and duration. Such electrical energy generating devices are known in the art as energy harvesting devices that are used to convert mechanical energy to electrical energy. An external LC circuit with shown in FIG. 8 is formed by a capacitor Cs and an inductor Ls. The resonant time constant of the tank circuit formed by external storage capacitor Cs and inductor Ls is selected to be at least four times longer than the rise time of the acceleration pulse, i.e., the rise time of the piezoelectric element generated voltage. shock-loading pulse. Once a prescribed acceleration pulse is detected, the current can flow from the piezoelectric element through the MOSFETS 2, 3 and 1 back to the piezoelectric element, FIG. 5. As a result, the piezoelectric generated charges flow into the LsCs circuit, and are stored in the capacitor Cs (the aforementioned storage capacitor) since the diodes D3 and D4 prevent their return to the piezoelectric element through the diode D3 or from the capacitor D4 to the inductor Ls.

It is appreciated by those skilled in the art that the piezoelectric-based electrical energy generator and its indicated charge collection and storage circuit can also harvest electrical energy from multiple similar relatively short duration acceleration pulses and add the generated electrical energy to the storage capacitor.

It is also appreciated by those skilled in the art that similar “electrical energy pulses” may be produced by electromagnetic or electrostatic or magnetostrictive transducers instead of piezoelectric transducer using appropriate mechanical interfacing mechanisms. In which case, the present integrated circuit (IC) 20, FIGS. 4 and 5 (40 FIGS. 6-8) may be used to efficiently collect and store the generated electrical energy in the storage capacitor Cs, FIG. 8.

The integrated circuit IC 20 based “self-powered acceleration pulse event detection device with false trigger protection logic and resetting capability” 30 of FIG. 4, also referred to shortly as “inertial switch 30”, was redrawn previously in FIG. 5 to describe the functionality of its various components. The primary functions performed by the components of the inertial switch 30 of FIG. 4 was presented by the three function blocks shown with dotted lines in FIG. 5. As can be seen in FIG. 5, the three function blocks are the “Self-powered acceleration pulse event detection with false trigger protection” block; the “Switch reset”; and the “Switching circuit” blocks.

As was previously described, when the piezoelectric element PZ1 of the inertial switch 30, which may be as shown in FIG. 1, is subjected to an acceleration pulse, such as an acceleration in the direction of the arrow 14 in FIG. 1, the piezoelectric element will generate an open-circuit charge profile such as the one shown in FIG. 3. The inertial switch 30 is designed to be capable of differentiating a prescribed acceleration pulse events as described by a minimum acceleration pulse magnitude and a minimum of its duration (the so-called all-fire events for the case of gun-fired munitions and mortars) from other acceleration events that may occur during manufacture, assembly, handling, transport, accidental drops, etc. The said event was also referred to as the “prescribed acceleration pulse event”.

To detect the occurrence of a prescribed acceleration pulse event, the profile of the charge voltage generated by the piezoelectric element PZ1 of the inertial switch 30 must satisfy the event minimum magnitude and its minimum duration conditions. In the inertial switch 30 of FIG. 5, as was previously described, the said magnitude and duration thresholds are configured by the resistance of the resistor R3 and the capacitance of the capacitor C1, both of which are external components to the integrated circuit embodiment 20.

In the inertial switch 30 of FIG. 5, the aforementioned magnitude threshold of the open-circuit piezoelectric charge voltage, which is proportional to the magnitude of the acceleration pulse experienced by the piezoelectric element and its duration is determined from the voltage of the capacitor C1. It is appreciated by those skilled in the art that under relatively low acceleration levels, such as those experienced during transportation induced vibration, the voltage across the piezoelectric element PZ1 is lower than the Z1 Zener diode voltage and since the diode D1 also blocks the current flow into the capacitor C1, the capacitor C1 stays discharged. In the integrated circuit 20, the Zener diode Z1 is generally used to set a minimum voltage threshold level for blocking charging of the capacitor C1 by charges generated by the piezoelectric element in response to low acceleration levels such as those due to transportation induced accelerations. At such low acceleration levels, no current will pass through the resistor R1 to charge the capacitor C1, and the MOSFET M1 is in cut-off mode and no current passes to the output ports. In general, the capacitance of the capacitor C1 is selected to be very low and the resistance of the resistor R1 is selected to be high so that a very small portion of the electrical energy generated by the piezoelectric element PZ1 is consumed by the Z1, R1 and C1 circuit.

In the inertial switch 30 of FIG. 5, the resistors R1 and R2 of the integrated circuit 20 are fixed and by selecting appropriate values for the resistance of the resistor R3 and the capacitance of the capacitor C1, the user sets the aforementioned acceleration pulse magnitude and duration thresholds for the inertial switch 30. In the integrated circuit 20, the MOSFET M1 functions as a signal switch, which is activated when its gate voltage level has been reached.

When the inertial switch 30 of FIG. 5 experiences an acceleration pulse, if the voltage of the charges generated by the piezoelectric element PZ1 passes the Z1 Zener diode voltage, the reverse biased Z1 diode passes current to the capacitor C1, and the capacitor begins to be charged. If the acceleration pulse amplitude passes the prescribed threshold level and lasts longer than the prescribed duration threshold, the gate voltage of the MOSFET M1 will be reached and it is activated. However, if the amplitude of the acceleration pulse is higher than the prescribed threshold level but its duration is below that of the prescribed duration threshold, then the gate voltage of the MOSFET M1 will not be reached, and it is not activated.

Once a prescribed acceleration pulse event has been detected by the detection of aforementioned minimum magnitude and its minimum duration (at the minimum magnitude), the MOSFET M1 is activated as is described above. Upon activation of the MOSFET M1, the capacitor C2 is charged up to a voltage level which is higher than the gate threshold voltage of the MOSFETs M2 and M3, and would allow current to flow in both directions. As a result, the normally open circuit between the integrated circuit (IC) 20 pins 7 and 8 is closed. The inertial switch 30 of FIG. 5 is thereby functions as a normally open inertial switch, which closes the said circuit (between the pins 7 and 8) upon detection of the prescribed acceleration pulse event.

It is, however, appreciated by those skilled in the art that when the inertial switch 30 of FIG. 5 experiences an acceleration pulse, if the amplitude of the acceleration pulse is significantly higher than the aforementioned prescribed threshold level (the so-called all-fire setback acceleration level for the case of gun-fired munitions and mortars), then the higher voltage of the charges generated by the piezoelectric element PZ1 would charge the capacitor C1 to the prescribed voltage threshold level a significant amount of time before the aforementioned acceleration pulse duration threshold has elapsed (i.e., before the so-called all-fire event for the case of gun-fired munitions and mortars is to be indicated). In some applications in which accidental acceleration amplitude levels could be significantly higher than the prescribed acceleration pulse magnitude threshold and that the acceleration pulse threshold is relatively short, this shortcoming of the aforementioned embodiments of the present invention may become unacceptable.

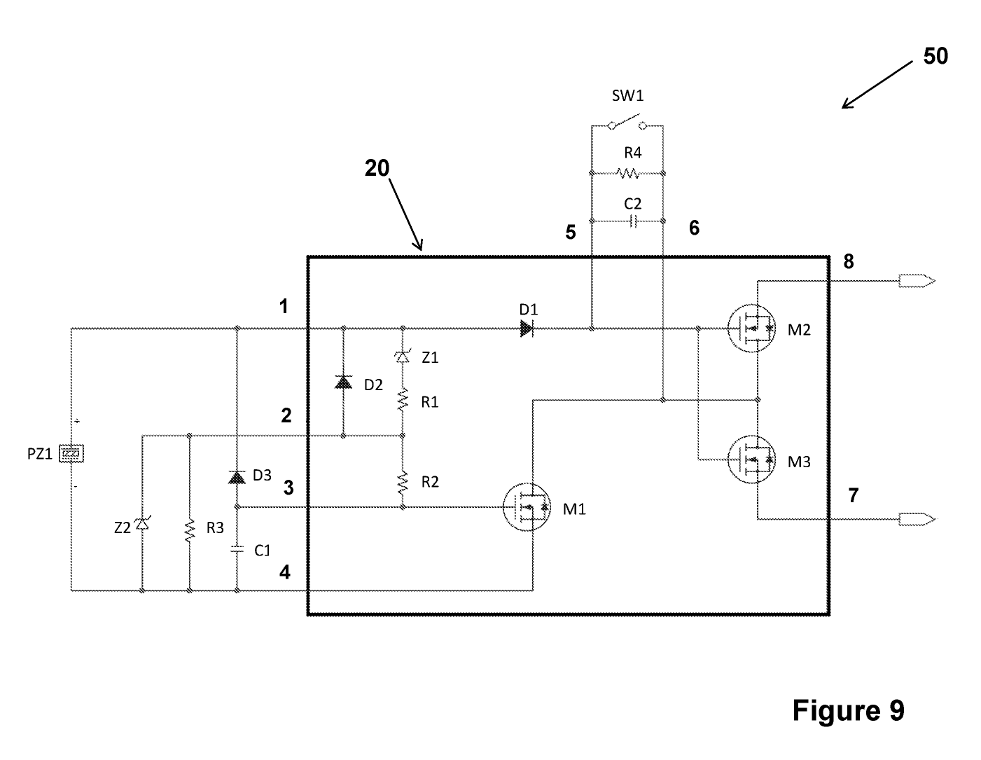

The “self-powered acceleration pulse event detection device with false trigger protection logic and resetting capability” 50 of FIG. 9, also referred to shortly as “inertial switch 50”, is designed to eliminate the aforementioned shortcoming of the aforementioned embodiments of the present invention. The embodiment 50 of FIG. 9 is provided with the means of limiting the voltage applied to the capacitor C1, FIG. 5, to a predetermined voltage as described below so that no matter how high the voltage of the charges generated by the device piezoelectric element is reached, i.e., no matter how high the acceleration pulse magnitude is experienced by the device, the duration of the pulse is detected based on the said predetermined acceleration pulse magnitude. As a result, the pulse duration of the acceleration pulse to be detected becomes independent of how much higher the peak acceleration pulse magnitude nay reach. The embodiment 50 of FIG. 9 would therefore become capable of differentiating a prescribed acceleration pulse event as described by a prescribed acceleration pulse magnitude and a minimum of its duration (the so-called all-fire events for the case of gun-fired munitions and mortars), no matter how high accidental (no-fire) acceleration pulse magnitudes the experienced by the device.

The inertial switch embodiment 50 of FIG. 9 has identical components as the embodiment 30 of FIG. 4, except for the piezoelectric and the external event detection circuitry connected to the pins 1, 2, 3 and 4. The inertial switch embodiment 50 uses the same integrated circuit (IC) 20 (FIGS. 4 and 5) and is configured to function similarly except that the charging voltage applied to the capacitor C1 and used to detect the aforementioned prescribed acceleration pulse magnitude threshold is limited at a preset level. As a result, the duration of the acceleration pulse for indicating the prescribed acceleration pulse event (such as the all-fire condition for munitions due to setback acceleration or due to an impact event) is determined at the said prescribed acceleration pulse magnitude threshold level, even if the magnitude of the acceleration pulse is significantly higher than the acceleration pulse magnitude threshold.

In the inertial switch embodiment 50 of FIG. 9, the external event detection circuitry connected to the pins 1, 2, 3 and 4 in addition to the piezoelectric element PZ1 (which was also similarly used in the previous embodiments of the present invention) consist of the Zener diode (Z2), the capacitor C1, the resistor R3 and the diode D3. As was described for the previous embodiments of the present invention, the piezoelectric transducer produces a charge (at certain voltage) profile when subjected to an acceleration pulse. And as was described for the inertial switch embodiments of FIGS. 4 and 5, the inertial switch output state is changed from its initial (pre-acceleration pulse) open state to its closed state if the piezoelectric generated charge (voltage) profile satisfies the aforementioned two conditions. Firstly, the magnitude of the piezoelectric generated voltage profile exceeds a prescribed voltage threshold (hereinafter indicated as the voltage Vₜₕ), and secondly if the magnitude of the piezoelectric generated voltage profile remains above the said prescribed voltage threshold Vₜₕ a prescribed amount of time, hereinafter indicated as the (time) duration t_{d}. The inertial switch embodiment 50 of FIG. 9 is designed as described below to activate, i.e., change from its initial (pre-acceleration pulse) open state to its activated closed state, when both of the above two (prescribed voltage magnitude threshold as well as duration) conditions are satisfied.

In the inertial switch embodiment 50 of FIG. 9, as was previously described the Zener diode Z1 inside the IC is used to prevent false activation due to currents generated by the piezoelectric transducer flowing into the circuit when subjected to continuous or small acceleration pulses and vibrations of the device. The Zener voltage (V_{Z1}) of Z1 significantly lower and the Zener voltage (V_{Z2}) of Z2 higher than any expected aforementioned prescribed voltage threshold Vₜₕ. For the given application, the resistance of the resistor R3 is used to set the capacitor C1 charging voltage to the desired level, in this case to the prescribed voltage threshold Vₜₕ. It is appreciated by those skilled in the art that as was previously indicated, the Z2 Zener voltage must be higher than the gate threshold voltage (V_{gth}) of the MOSFET M1. Then for a prescribed voltage threshold Vₜₕ and given values of the IC (20 in FIG. 9) resistance R1 and Zener voltage V_{Z1} and a given Zener voltage V_{Z2}, the required resistance of the external resistor R3 can be calculated from the following equation

$$R 3 = \frac{\frac{{V}_{Z 2}}{{V}_{th} - {V}_{Z 1}}}{( 1 - \frac{{V}_{Z 2}}{{V}_{th} - {V}_{Z 1}} )} \times R 1$$

In addition, the capacitance of capacitor C1 is used to set the duration of the time t_{d} that the piezoelectric voltage level, i.e., the acceleration pulse magnitude, must be above its prescribed threshold until the voltage on the capacitor C1 reaches its prescribed threshold for activating the inertial switch as was described for the embodiments of FIGS. 4 and 5. The capacitor C2, when used, perform the functions to suppress noise and to keep the activated inertial switch in its activated state (remain latched).

It is appreciated by those skilled in the art that by examining the inertial switch embodiment 50 of FIG. 9, as the piezoelectric transducer is subjected to an acceleration pulse (shock loading) event, one of the following four basic scenarios could be faced and can be seen to ensure proper operation of the inertial switch as was previously described.

The first scenario is the case in which the voltage of the piezoelectric generated charges stays below the Zener Z1 voltage V_{Z1}, thereby no current can flow from the piezoelectric transducer through Z1 and the inertial switch embodiment 50 of FIG. 9 remains open, i.e., it is not activated.

The second scenario is the case in which the voltage of the piezoelectric generated charges goes beyond the Zener Z1 voltage V_{Z1} but stays below the aforementioned prescribed voltage threshold Vₜₕ. In this case, the capacitor C1 begins to be charged, but no matter how long the voltage of the piezoelectric generated charges stays above the Zener Z1 voltage V_{Z1}, the voltage of the capacitor C1 stays below the gate threshold voltage (V_{gth}) of the MOSFET M1. As a result, the inertial switch embodiment 50 of FIG. 9 remains open, i.e., it is not activated.

The third scenario is the case in which the voltage of the piezoelectric generated charges goes beyond the Zener Z1 voltage V_{Z1} and the aforementioned prescribed voltage threshold Vₜₕ, but stays beyond the said voltages less than the aforementioned prescribed (time) duration t_{d}. In this case, since the time required for voltage across C1 (V_{C1}) to reach the gate threshold voltage V_{gth} of the MOSFET M1 is selected to be the said prescribed (time) duration t_{d}, the capacitor C1 voltage V_{C1} does not reach the gate threshold voltage V_{gth} of the MOSFET M1, and the MOSFET M1 remains in cut-off mode. As a result, the inertial switch embodiment 50 of FIG. 9 remains open, i.e., it is not activated.

The fourth scenario is the case in which the voltage of the piezoelectric generated charges goes beyond the Zener Z1 voltage V_{Z1} and the above prescribed voltage threshold Vₜₕ and stay beyond the said voltage levels at least as long as the aforementioned prescribed (time) duration t_{d}. In this case, the capacitor C1 is charged to a voltage that is higher than the gate threshold voltage V_{gth} of the MOSFET M1, thereby causing the MOSFET M1 to be activated. Once the MOSFET M1 is activated, voltage potential is established across the capacitor C2, which preferably has a very small capacitance so that it is rapidly charged and does not consume too much of the electrical energy generated by the piezoelectric element. In this circuit, the diode D2 is used to prevent the current from flowing back from the capacitor C2 to the piezoelectric transducer. The combination of MOSFETs M2 and M3 forms a unipolar solid state relay and the connection pins 8 and 7, FIG. 9, are the 2 terminals of the electronic inertial switch. Thus, the inertial switch embodiment 50 of FIG. 9 closes, i.e., it is activated, and electrical current can flow between connection pins 7 and 8.

It is appreciated by those skilled in the art that the use of the resistor R4 and the switch SW1 are optional components. By providing these two components as shown in FIG. 9, the activated electronic inertial switch can be reset at any time by simply closing of the switch SW1.

While there has been shown and described what is considered to be preferred embodiments of the invention, it will, of course, be understood that various modifications and changes in form or detail could readily be made without departing from the spirit of the invention. It is therefore intended that the invention be not limited to the exact forms described and illustrated, but should be constructed to cover all modifications that may fall within the scope of the appended claims.

What is claimed is:

1. An inertial switch comprising:
piezoelectric and external event detection circuitry.
